(19) United States
(12) Patent Application Publication
(10) Pub. No.: US 2019/0355607 A1
(43) Pub. Date: Nov. 21, 2019

(54) THERMALLY ISOLATED ELECTRONICS UTILITIES CAVITY FOR A SUBSTRATE CARRIER

(71) Applicant: Applied Materials, Inc., Santa Clara, CA (US)

(72) Inventors: Shreesha Y. RAO, Milpitas, CA (US); Joseph VINCENT, Bangalore (IN); Wenwei QIAO, Gilroy, CA (US); John M. WHITE, Hayward, CA (US)

(21) Appl. No.: 15/986,452

(22) Filed: May 22, 2018

(30) Foreign Application Priority Data
May 21, 2018 (IN) 20184108921

(51) Int. Cl. H01L 21/683; H01L 21/67; H01M 2/10

(52) U.S. Cl. CPC H01L 21/6833; H01J 37/32697; H01M 2/1094; H01L 21/67017

(57) ABSTRACT

Described herein is a substrate carrier comprises a plurality of electrostatic chuck panels and a carrier body. The plurality of electrostatic chuck panels is disposed on the carrier body. The carrier body has an electronics utilities cavity, and a thermal insulating material disposed on at least one wall of the electronics utilities cavity. A battery is disposed within the electronics cavity, and is configured to provide a first power supply signal to control electronics. The carrier body may additionally include a first body member having the electrostatic chuck panels disposed thereon, and a second body member separated from the first body member by thermal breaks. The electronics utilities cavity may be housed within the second body member of the carrier body.

### CROSS-REFERENCE TO RELATED APPLICATION

This application claims benefit of priority to Indian Provisional Application Ser. No. 201841018921, filed on May 21, 2018, which is incorporated herein by reference in its entirety.

### BACKGROUND

### Field

Embodiments described herein generally relate to regulating the environmental temperature of a battery within a substrate carrier.

### Description of the Related Art

In the processing of substrates, such as semiconducting substrates and displays, the substrate is held on a substrate support surface of a substrate carrier or substrate support in a process chamber during processing. The substrate support surface can include an electrostatic chuck (ESC) that has one or more electrodes capable of being electrically biased to hold the substrate to the substrate support surface. Typically, each ESC is coupled to power supply which is controlled by control electronics. The control electronics are powered by a low voltage power supply, which may be a battery. However, as the control electronics and low voltage power supply are housed within the substrate carrier, they are exposed to high temperatures and changing pressures while in the processing chamber. These conditions may cause one or more of the control electronics and low voltage power supply may fail while processing the substrate, which may cause catastrophic damage to the substrate.

Thus there is a need to provide a substrate carrier having a low voltage power supply and control electronics that are protected from the high processing temperatures and the changing operating pressures.

### SUMMARY

In one embodiment, a substrate carrier comprises a plurality of electrostatic chuck panels, a carrier body having the electrostatic chuck panels disposed thereon. The carrier comprises an electronics utilities cavity, a battery disposed within the electronics cavity and configured to provide a first power supply signal to control electronics, and a thermal insulating material disposed on at least one wall of the electronics utilities cavity.

In another embodiment, a substrate carrier comprises a plurality of a plurality of electrostatic chuck panels, and a carrier body. The carrier body comprises a first body member having the electrostatic chuck panels disposed thereon, and a second body member separated from the first body member by thermal breaks. Further, the carrier body comprises an electronics utilities cavity disposed within the second body member, a battery disposed within the electronics cavity and configured to provide a first power supply signal to control electronics, and a thermal insulating material disposed on at least one wall of the electronics utilities cavity.

In one embodiment, a carrier body for a substrate carrier having a plurality of electrostatic chuck panels includes a first body member, a second body member, and an electronics cavity. The first body member is configured to have the electrostatic chuck panels disposed thereon and is separated from the second body member by thermal breaks. Further, the electronics utilities cavity is disposed within the second body member. The carrier body further includes control circuitry, a high voltage power source configured to provide a second power supply signal, and a battery configured to provide a first power supply signal to control electronics and the high voltage power supply signal. Further, a thermal insulating material disposed on at least one wall of the electronics utilities cavity. The high voltage power source is configured to supply a second power supply signal, and the battery is configured to provide a first power supply signal to the control electronics and the high voltage power supply. The first power supply signal is a lower voltage than the second power supply signal.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic perspective view of a substrate carrier with an integrated ESC according to one embodiment disclosed herein.

FIG. 1B illustrates a front cut-away view of a substrate carrier according to an embodiment disclosed herein.

FIG. 2 illustrates an a carrier body according to one or more embodiments.

FIG. 3 illustrates a portion of a carrier body according to one or more embodiments.

FIGS. 4 and 5 illustrate electronics utilities cavities according to one or more embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Described herein are substrate carriers having a battery housed within an electronics utilities cavity and that is thermally isolated from high processing temperatures. One or more of the internal walls of the electronics utilities cavity may have a thermal isolating material disposed thereon. Further, the electronics utilities cavity may be disposed within a body member of a corresponding substrate carrier that is separated from another body member of the substrate carrier by thermal breaks, providing additional thermal isolation of the battery and control electronics housed within the electronics utilities cavity. Thermally isolating the battery and control electronics decreases the likelihood that the battery and/or control electronics will suffer a failure when the substrate carrier is exposed to high temperatures and changing pressures during substrate processing.

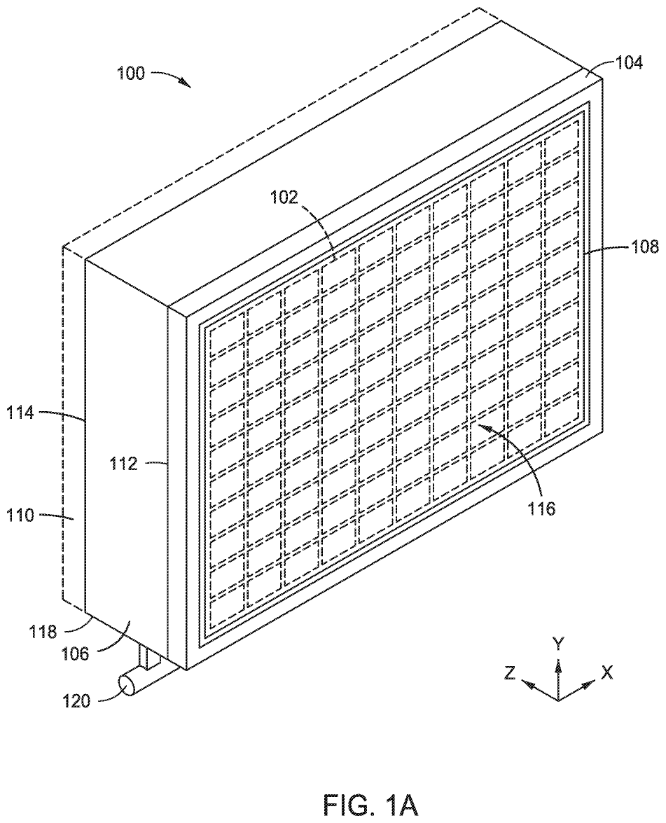

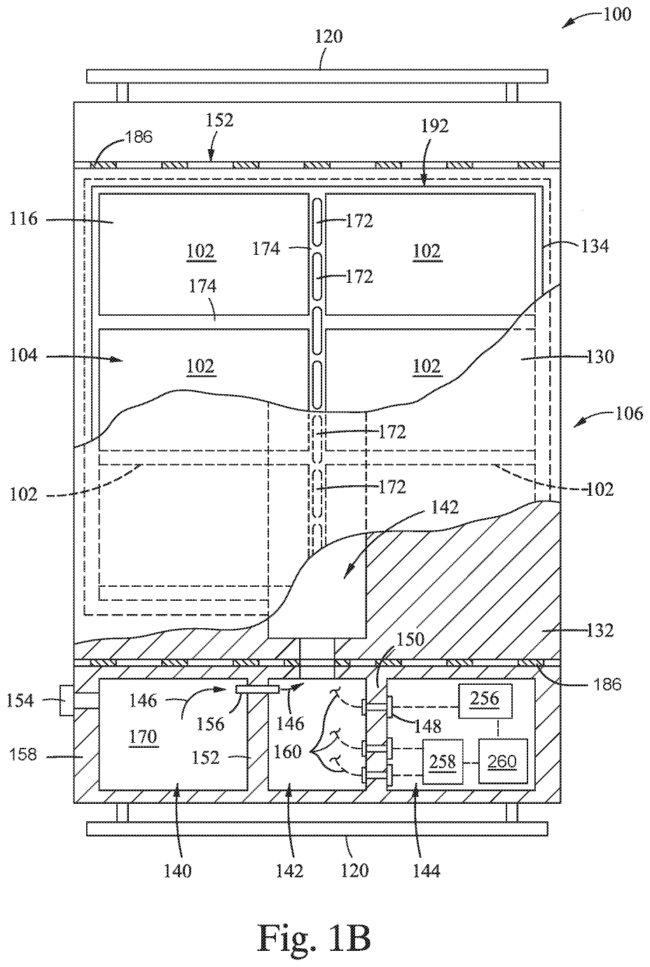

FIG. 1A is a schematic perspective view of a substrate carrier 100 having an ESC 104 thereon, according to one embodiment disclosed herein. The ESC 104 enables the substrate carrier 100 to transport and support a large area substrate while moving between processing and other chambers. In one example, the ESC 104 can be configured to support one or more substrates and may have a substrate support surface 116 of at least 0.174 square meters (m²). In general, the size of the substrate support surface 116 of the ESC 104 may be between 1 m² and about 12 m², for example, between about 2 m² and about 9 m². In other examples, the substrate support surface 116 of the ESC 104 may be adapted for transporting one or more large area substrates, such as substrates having a plan area of about 1.4 m² and greater.

The substrate may be made from any material suitable for material deposition, such as, for an OLED fabrication processes, among other processes. For example, the substrate may be made from materials such as glass (e.g. soda lime glass, borosilicate glass, etc.), metal, polymer, ceramic, compound materials, carbon fiber material and combinations thereof.

The carrier 100 may be used to transport the substrate during a plasma process, including chemical vapor deposition (CVD) processes, physical vapor deposition (PVD) processes, etching processes, or any suitable plasma or vacuum process, for example, OLED display manufacturing processes. The ESC 104 may also be adapted for use in non-plasma and non-vacuum environments and may be compatible for high temperature applications. Although various embodiments of the carrier 100 are disclosed herein, it is contemplated that electrostatic chucks from other manufacturers may be adapted to benefit from the disclosure provided herein.

The substrate carrier 100 is adapted to transport a substrate held on the substrate support surface 116 of the ESC 104. The substrate carrier 100 includes the ESC 104, a carrier body 106, an optional backside ESC 110, and an optional translational member 120. When utilized, a backside ESC 110 is used to hold one or more second large area substrates on the opposite side of the carrier body 106. The backside ESC 110 may be fabricated substantially identical to the ESC 104.

The ESC 104 includes a chuck body 108 and a plurality of independently replaceable electrostatic chuck panels 102. The electrostatic chuck panels 102 of the ESC 104 form the substrate support surface 116 of the ESC 104. The electrostatic chuck panels 102 may be arranged in a Cartesian array (i.e., a 2-dimential array of rows and columns) or other pattern across the substrate support surface 116. Each electrostatic chuck panel 102 may be independently replaced without disturbing the other electrostatic chuck panels 102 of the ESC 104, making repair and reconditioning of the ESC 104 more rapid and less costly.

The chuck body 108 may be made of ceramic or other material, such as aluminum. In some embodiments, the chuck body 108 and carrier body 106 may be fabricated as a single component, and as such, reference to the chuck body 108 and carrier body 106 may be utilized interchangeably. In such embodiments, the electrostatic chuck panels 102 are mounted directly to the chuck body 108. The chuck body 108 is disposed on a first surface 112 of the carrier body 106. The optional backside ESC 110 may be disposed on a second surface 114 of the carrier body 106 opposite the first surface 112. The optional translational member 120 may be coupled to a bottom surface 118 of the carrier body 106. The bottom surface 118 extends between the first surface 112 and the second surface 114.

FIG. 1B is a front cut-away view of the substrate carrier 100. The substrate carrier 100 is shown with a reduced number of electrostatic chuck panels 102 included in the ESC 104 as compared to the illustrations of FIG. 1A. In FIG. 1B, the electrostatic chuck panels 102 are shown partially cut away to expose base plate 132 and one or more cavities which may be covered with one or more cover plates (not shown) The base plate 132 includes a number of cavities that are covered or enclosed by one or more cover plates. The cavities formed in the base plate 132 include one or more of a gas cavity 140, a gas delivery manifold cavity 142, and an electrical utilities cavity 144. Although the gas and electronics utilities cavities 140, 144 may be arranged in any location within the substrate carrier 100, in the embodiment depicted in FIG. 1B, the cavities 140, 144 are positioned at the bottom of the substrate carrier 100, for example adjacent the translational member 120, when present. In one embodiment a single cover plate is disposed over cavities 140, 142, and 144. In another embodiment, a first cover plate is disposed over cavity 140, a second cover plate is disposed over cavity 142, and a third cover plate is disposed over cavity 144. In one embodiment, cavity 142 is split into an upper and lower portion, and each portion may be covered by two separate cover plates. For example, gas delivery manifold cavity 142 may include an upper portion and a lower portion, where each portion is covered by a different cover plate. Each cover plate may include an 0-ring or other sealing member to seal each corresponding cavity from the process chamber vacuum.

In various embodiments, the cavities 140 and 144 are positioned the planar extents (i.e., not overlapping) with the electrostatic chuck panels 102, which advantageously prevents heat from being transferred from the substrate to electrostatic chuck panels 102, and the base plate 132, thus preventing the cavities 140, 144 from being excessively heated. Thus, the functioning of the electrical components present in the electrical utilities cavity 140 and pressure of the gas contained in the gas cavity 140 are also protected from being excessively heated. Further, in one embodiment, a lower portion of gas delivery manifold cavity 142 is also disposed beyond the planar extents with the electrostatic chuck panels.

The electrical utilities cavity 144 is separated from the gas delivery manifold cavity 142 by a first interior wall 150. The electrical utilities cavity 144 houses the ESC control electronics 256, high voltage power source 258 and battery 260. In one embodiment, the battery and a high voltage power source are configured to operate the electrostatic chuck panels 102. The high voltage power source may include a high voltage operational amplifier. In one embodiment, the battery may be used to power control electronics 256 which are configured to control the high voltage power source 258 to provide high voltage to the electrostatic chuck panels 102. Electrical vacuum feed-throughs 148 are formed through the wall 150 to facilitate routing of the leads 160 between the control electronics 256 and the high voltage power supply 258, and the electrostatic chuck panels 102 disposed on the cover plate 130.

The gas cavity 140 is separated from the gas delivery manifold cavity 142 by a second interior wall 152. The gas cavity 140 is configured to function as the gas source 170. The gas cavity 140 may be charged with gas via a self-sealing quick disconnect fitting 154 mounted through an exterior wall 158 of the base plate 132. For example, an external gas source (not shown) may be temporarily coupled to the quick disconnect fitting 154 to allow gas cavity 140 to be charged (i.e., pressurized) with a gas that will be utilized as a backside gas between the electrostatic chuck panels 102 and the substrate chucked thereon. The backside gas may be used to transfer heat from the substrate to the electrostatic chuck panels 102, and then to the thermal mass of the base plate 132.

In on embodiment, the volumetric size of the gas cavity 140 may be selected to provide a sufficient volume of backside gas between the substrate and the electrostatic chuck panels 102 to last for the duration in which the substrate is processed while being held on the substrate carrier 100 between recharging of the gas cavity 140 through the quick disconnect fitting 154. Thus, the volume size of the gas cavity 140 may be selected in consideration of the size substrate, the amount of backside gas escaping from under the edge of the substrate, and the expended duration between recharging of the gas cavity 140. In one embodiment, the volumetric size of the gas cavity 140 is between about 1 and about 10 liters.

At least one aperture is formed through the second interior wall 152 to fluidly couple the gas delivery manifold cavity 142 to the gas cavity 140. The aperture 156 may be configured to control the flow of gas between the gas cavity 140 and the gas delivery manifold cavity 142. Further, in one embodiment, the aperture 156 is configured to stop the flow of gas once the gas delivery manifold cavity 142 is considered to be full. However, as the backside gas may leak from under the edge, the gas cavity 140 may be configured to recharge the gas delivery manifold to compensate for any gas that is lost due to leakage. For example, the aperture 156 may have a small orifice so that gases disposed in the gas cavity 140 flow into the gas delivery manifold cavity 142 (as shown by arrows 146) at a rate sufficiently slow enough to provide a sufficient amount of backside gas between the substrate and the electrostatic chuck panels 102 to last for the duration that the substrate is processed. Optionally, the flow through the aperture 156 may be controlled by a valve (not shown). The valve may be an on/off valve, or a needle valve operable to control the flow out of the gas cavity 140 flow into the gas delivery manifold cavity 142 through the aperture 156.

The gas delivery manifold cavity 142 generally extends below the portion of the substrate carrier 100 upon which the electrostatic chuck panels 102 are mounted. The gas delivery manifold cavity 142 provides an electrical conduit for routing the leads 160 between the electrostatic chuck panels 102 and the one or more power sources 258.

The gas delivery manifold cavity 142 is also utilized to route the backside gas from the cavity 140 (i.e., the gas source 170) to the one or more apertures 172 formed through the cover plate 130. The backside gas flowing through the one or more apertures 172 flows between the grooves 174 between the electrostatic chuck panels 102 across the surface of the substrate carrier 100 to enhance heat transfer between the electrostatic chuck panels 102 and the substrate chucked thereto.

In the embodiment shown in FIG. 1B, the gas delivery manifold 142 is formed in the base plate 132 and is enclosed by a cover plate. The gas delivery manifold 142 has a substantially elongated shape and extends from the bottom of the base plate 132 adjacent the gas cavity 140 to the top of the substrate carrier 100. In one embodiment, the gas delivery manifold 142 may include an upper and lower portion. The upper and lower portions may be are connected via a thermal break 186 having an opening. For example, one or more the thermal breaks 186 may include an opening to allow the free flow of gas and electrical routings there between. Further, one or more sealing members may be formed within a thermal break and/or within the carrier 100 proximate the cavity to prevent gas from escaping.

The gas delivery manifold cavity 142 may be generally aligned below the interface between adjacent electrostatic chuck panels 102 so that the apertures 172 formed in a cover plate may be generally aligned in a column when fluidly connecting the grooves 174 between the adjacent electrostatic chuck panels 102 and the gas delivery manifold 142 through the apertures 172. Thus, the backside gas may freely flow from gas delivery manifold 142 through the apertures 172 and into the grooves 174 between the facing edges of the adjacent electrostatic chuck panels 102 that are aligned above the gas delivery manifold 142. Once the backside gas is in the grooves 174 aligned in a first direction above the gas delivery manifold cavity 142, the backside gas flows laterally outward into the adjacent grooves 174 that are arranged in a second direction between adjacent electrostatic chuck panels 102 that extend laterally away from the gaps grooves above the apertures 172. For example, the backside gas fed from the apertures 172 into the grooves 174 aligned in the first direction flows orthogonally into the grooves 174 that are aligned in the second direction. That is, the first direction is orthogonal to the second direction.

In one example, the grooves 174 that are aligned in the second direction are not in direct fluid communication with the apertures 172 except as provided by connection with the grooves 174 that are aligned in the first direction. The grooves 174 that are aligned in the second direction may also provide gas into the channel 134 disposed below the unsupported portion 192 of a lip seal in addition or alternatively to the channel 134 being provide with gas from the gas source or the fluid source.

In various embodiments, regions of the carrier 100 are separated from each other by thermal breaks c disposed between regions. The thermal breaks 186 help reduce the amount of heat transferring from the region of the substrate carrier 100 on which the electrostatic chuck panels 102 are mounted to the region of the substrate carrier 100 that contains the gas cavity 140 and the electrical utilities cavity 144. Thus, the thermal breaks 186 advantageously keep the gases within the gas cavity 140 from heating, while also keeping the control electronics 256 and the one or more power sources 258 disposed in the electrical utilities cavity 144 from heating.

In one example, the thermal break 186 may include one or more slots formed across one or both of the cover plate and the base plate 132. The slots may be formed in both the cover plate and the base plate 132. Further, the slots may be filled with a material having a thermal conductivity less than the thermal conductivity of the cover plate 130 and the base plate 132.

The thermal breaks 186 may be fabricated from a material having a thermal conductivity less than the thermal conductivity of the cover plates and the base plate 132. Suitable materials for fabricating the thermal breaks 186 include ceramics and polymers. In the example depicted in FIG. 1B, the thermal breaks 186 are fabricated from an organic thermoplastic polymer such as polyaryletherketone (PAEK), for example polyether ether ketone (PEEK). In one embodiment, the thermal breaks 186 are fabricated within carrier 100 by machining a plurality of slots in the carrier 100 to form the thermal breaks 186. Further, one or more of the thermal breaks may include an opening allow for gases and electrical connections to pass between the cavities and the electrostatic chuck panels.

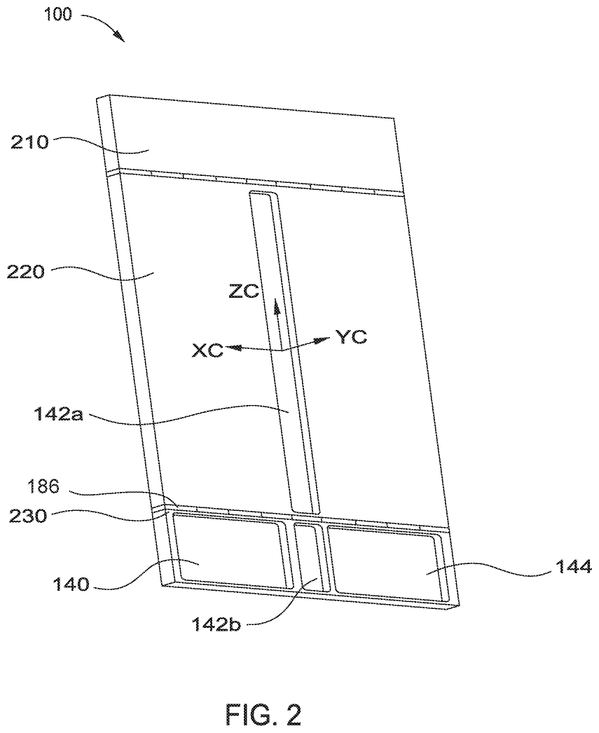

In various embodiments, carrier 100 may be formed of a single body construction. In such an embodiment, one or more cavities may be formed in the carrier 100 to thermally isolate the electrical utilities cavity 144 and the gas cavity 142. In other embodiments, carrier 100 includes multiple bodies attached together. FIG. 2 illustrates one embodiment of carrier 100 comprising three separate body members, an upper body member 210, a center body member 220 and a lower body member 230. The upper, center and lower body members are attached together, forming the carrier 100. Further, while not illustrated electrostatic chuck panels would be disposed over the center body member 220, and the center body member 220 includes an upper portion 142a of gas delivery manifold cavity 142. Lower body member 230 includes gas cavity 140, electrical utilities cavity 144 and a lower portion 142b of gas delivery manifold cavity 142. Further an upper body member 210 is attached to center body member 220.

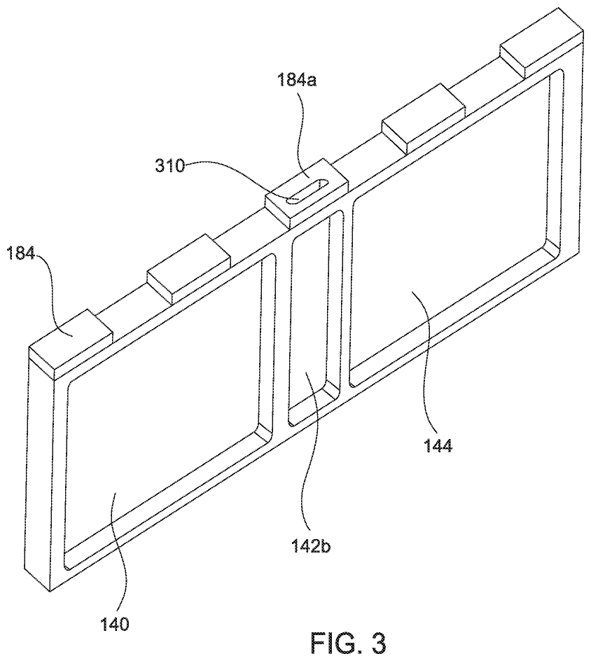

In one embodiment, center body member 220 is separated from lower body member 230 by one or more thermal breaks 186. Further, the upper portion 142a and lower portion 142b of gas delivery manifold cavity 142 are coupled via an opening in one of the thermal breaks 186. As illustrated in FIG. 3, thermal break 186a includes opening 310. Opening 310 provides a passageway for gases and electrical wiring to pass from lower portion 142b to upper portion 142a of gas delivery manifold cavity 142.

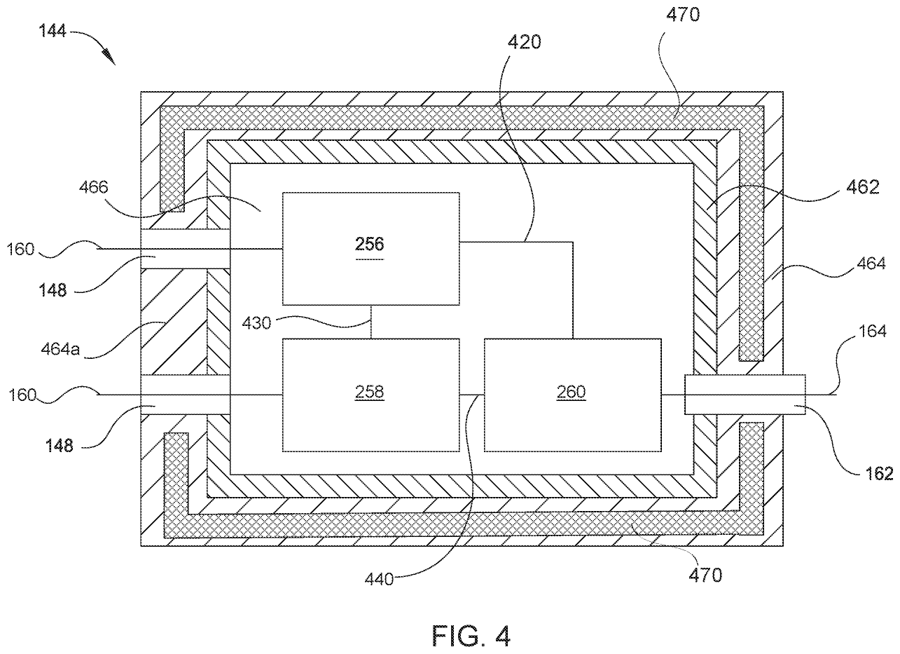

FIG. 4 illustrates an electrical utilities cavity 144 comprising control electronics 256, high voltage power supply 258, battery 260. Further, electrical utilities cavity 144 includes a thermal insulating material 462 and internal volume 466. Additionally, electrical utilities cavity 144 includes electrical vacuum feed throughs 148 and 162. As is illustrated, the battery 260 is coupled to control electronics 256 through one or more leads 420. Further, the battery 260 may be coupled to high voltage power supply 258 through one or more leads 440 and control electronics 256 may be coupled to high voltage power supply 258 through one or more leads 430.

Battery 260 is a rechargeable battery. For example, battery 260 may be a lithium-ion battery, nickel metal hydride battery, or the like. Further battery 260 may have one of a rectangular and a cylindrical shape.

As is mentioned above, carrier 100 is configured to support one or more substrates during processing, and during processing the carrier 100 may be exposed to temperatures that exceed the operating temperature of battery 260 and pressures that may promote electrical arcs. For example, the carrier 100 may be exposed to temperatures at or above 120 degrees Celsius while the desired operating temperature of the battery 260 is about 60 degrees Celsius.

Lining the interior of the walls of electrical utilities cavity 144 with a thermal insulating material isolates the internal volume 466 and battery 260 from the excessive processing temperatures, such that the internal temperature of the electrical utilities cavity 144 may be kept at or below the operating temperature of the battery 260. In one embodiment, the battery 260 comprises an operating temperature of about 60 degrees Celsius. In other embodiment, the operating temperature of the battery may be greater or less than 60 degrees Celsius. For example, in one embodiment, the operating temperature of the battery 260 may be at least 100 degrees Celsius. The operating temperature may refer to the charge and/or discharge temperature of the battery. The charge and discharge temperatures may be the same, or one of the charge and discharge temperatures may be greater than the other.

In one embodiment, the thermal insulating material 462 is disposed on the interior of walls 464. In one embodiment, the thermal insulating material 462 is applied to each of the walls 464. In one embodiment, the thickness of the thermal insulating material 462 is configured to maintain an inner temperature of internal volume 466 at or below the operating temperature of the battery 260. Further, a thermal insulating material maybe selected to maintain an inner temperature of internal volume 466 at or below the operating temperature of the battery 260.

In one embodiment, the thermal insulating material 462 creates a temperature gradient from outside the electrical utilities cavity 144 to internal volume 266, such that the internal volume remains at or below the safe maximum operating temperature of battery 260.

The thermal insulating material 462 may be a ceramic material, a yttria-stablized zirconia coating, fiberglass, PEEK, mineral wool, polyurethane foam, or the like. Further, the thermal insulating material 462 may be spray coated, printed or the like.

In one embodiment, the internal volume 466 of electrical utilities cavity 144 is maintained at about atmospheric pressure (about 1 ATM). By maintaining the internal volume 466 at about atmospheric pressure, electronic components within the cavity are preventing from going through the paschen curve during pumping of the vacuum chamber. Thus, the chance of arcing occurring or electrical failure of the battery 260 and any other power sources and electronic components within the cavity 144 is reduced when used in a vacuum chamber.

Electrical utilities cavity 144 may include one or more sealing members 470 configured to seal the inner volume 466 from an external processing environment. In one embodiment, the sealing members 470 are disposed within grooves in the wall 464 such that when a cover plate is disposed over the cavity, the inner volume is sealed from the external processing environment.

In one or more embodiments, leads 160 are routed through electrical vacuum feed through 148. In various embodiments, one or more leads may be passed through each electrical vacuum feed through 148. Further, electrical vacuum feed-through 148 are formed through a wall 464a of electrical utilities cavity 144 to facilitate routing of a lead between the control electronics 256 and the high voltage power supply 258 and the electrostatic chuck panels 102. In one embodiment, one or more electrical vacuum feed through may be disposed more than one wall of the electrical utilities cavity 144.

The embodiment of FIG. 4 further includes vacuum feed through 162 that provides a passageway for one or more leads 164 from outside carrier 100 to be coupled to battery 260. In one embodiment, these leads may be used to recharge battery 260 as the battery 260 powers the high voltage power supply 258 and/or control electronics 256.

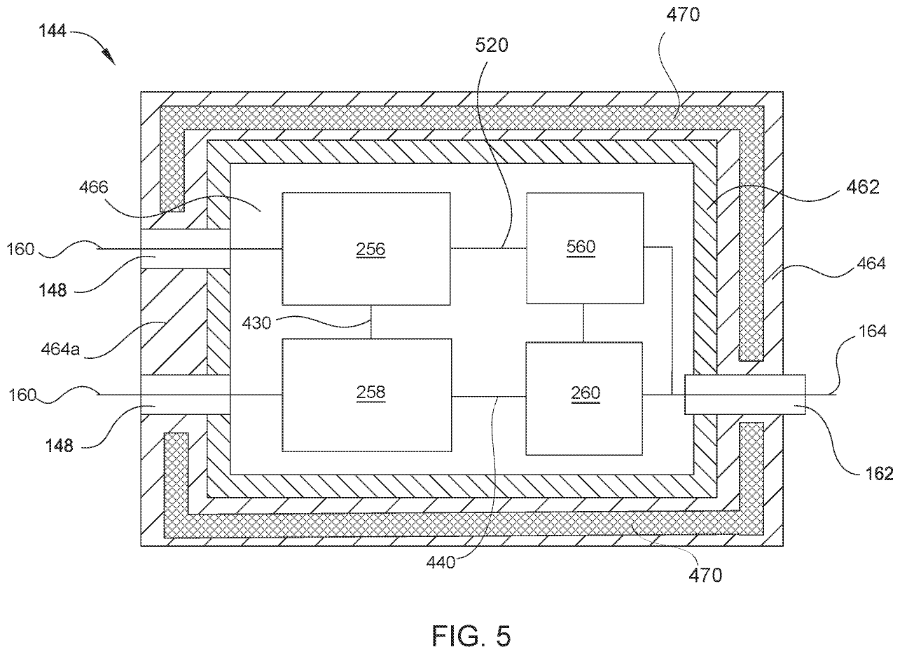

FIG. 5 illustrates an additional embodiment of electrical utilities cavity 144. As illustrated, the electrical utilities cavity 144 comprises control electronics 256, high voltage power supply 258, and batteries 260 and 560.

In one embodiment, battery 560 is coupled to control electronics 256 via one or more leads 520 and battery 260 is coupled to high voltage power supply 258 via the one or more leads 440. Battery 560 may be configured to power control electronics 256 and battery 258 may be configured to power high voltage power supply 258. In another embodiment, one or more leads may couple battery 560 with battery 260 such that the batteries function together to power control electronics 256 and high voltage power supply 258. Further, while two batteries are shown in FIG. 5, in other embodiments, more than two batteries may be utilized.

In other embodiments, each of batteries 260 and 560 may be independently coupled to control electronics 256 and high voltage power supply 258. Each of the batteries 260 and 560 may be utilized to power control electronics 256 and high voltage power supply 258. Further, in one example embodiment, batteries 260 and 560 may function as redundant power supplies, such that if one of the batteries fails, the other battery may be used to power the control electronics 256 and high voltage power supply 258.

Each battery 260 and 560 is coupled via one or more leads 164 to an external power source to recharge the batteries. In one embodiment, battery 560 is recharged by an external power source and battery 560 is used to recharge battery 260 which may be used to power control electronics 256 and/or high voltage power supply 258. In another embodiment, batteries 260 and 560 are each coupled with an external power source for recharging.

While the foregoing is directed to embodiments described herein, other and further embodiments may be devised without departing from the basic scope thereof, and the scope thereof is determined by the claims that follow.

What is claimed is:

1. A substrate carrier comprising
a plurality of electrostatic chuck panels;
a carrier body having the electrostatic chuck panels disposed thereon, the carrier body comprising:
an electronics utilities cavity;
a battery disposed within the electronics cavity and configured to provide a first power supply signal to control electronics; and
a thermal insulating material disposed on at least one wall of the electronics utilities cavity.

2. The substrate carrier of claim 1, wherein the thermal insulating material is one of a ceramic material, a yttria-stablized zirconia coating, fiberglass, PEEK, mineral wool, and polyurethane foam.

3. The substrate carrier of claim 1, wherein the thermal insulating material is disposed on each wall of the electronics utilities cavity.

4. The substrate carrier of claim 1, wherein the carrier body further comprises:
a first body member; and
a second body member, and
wherein the electronics utilities cavity is disposed within the second body member and the electrostatic chuck panels are disposed over the first body member.

5. The substrate carrier of claim 4, wherein the carrier body further comprises thermal breaks disposed between the first body member and the second body member.

6. The substrate carrier of claim 5, wherein each of the thermal breaks has a thermal conductivity lower than a thermal conductivity of the first and second body members.

7. The substrate carrier of claim 1, further comprising a high voltage power supply disposed in the electronics utilities cavity, the high voltage power supply is configured to provide a second power supply signal to the plurality of electrostatic chuck panels, wherein the first power supply signal is a lower voltage than the second power supply signal.

8. The substrate carrier of claim 7, wherein the battery is configured to power the high voltage power supply.

9. The substrate carrier of claim 1, wherein the electronics utilities cavity comprises one or more vacuum feedthroughs, and wherein a first lead is coupled to the battery through the one or more vacuum feedthroughs, and is configured to couple the battery with an external power source.

10. The substrate carrier of claim 1 further comprising a second battery disposed within the electronics cavity.

11. The substrate carrier of claim 1, wherein the electronics utilities cavity is configured to maintain an internal volume of the electronics utilities cavity at about 1 ATM.

12. A substrate carrier comprising
a plurality of electrostatic chuck panels;
a carrier body comprising:
a first body member having the electrostatic chuck panels disposed thereon;
a second body member separated from the first body member by thermal breaks;
an electronics utilities cavity disposed within the second body member;
a battery disposed within the electronics cavity and configured to provide a first power supply signal to control electronics; and
a thermal insulating material disposed on at least one wall of the electronics utilities cavity.

13. The substrate carrier of claim 12, wherein the carrier body is comprised of a first material and the thermal breaks are comprised of a second material having a lower thermal conductivity than the first material.

14. The substrate carrier of claim 12, wherein the thermal breaks and the carrier body are comprised of a common material.

15. The substrate carrier of claim 12, wherein the carrier body further comprises a gas delivery manifold cavity having an upper portion and a lower portion, and wherein one of the thermal breaks comprises an opening providing a passageway between the upper portion and the lower portion of the gas delivery manifold.

16. The substrate carrier of claim 12, further comprising a high voltage power supply disposed in the electronics utilities cavity, the high voltage power supply is configured to provide a second power supply signal to the plurality of electrostatic chuck panels, wherein the first power supply signal is a lower voltage than the second power supply signal, and wherein the battery is configured to power the high voltage power supply.

17. The substrate carrier of claim 12, wherein the electronics utilities cavity comprises one or more vacuum feedthroughs, and wherein a first lead is coupled to the battery through the one or more vacuum, and the first lead is configured to couple the battery with an external power source.

18. The substrate carrier of claim 12, wherein the thermal insulating material is disposed on each wall of the electronics utilities cavity.

19. A carrier body for a substrate carrier having a plurality of electrostatic chuck panels, the carrier body comprising:
a first body member configured to have the electrostatic chuck panels disposed thereon;
a second body member separated from the first body member by thermal breaks;
an electronics utilities cavity disposed within the second body member;
control electronics disposed within the electronics utilities cavity;
a high voltage power supply disposed within the electronics utilities cavity, and configured to supply a second power supply signal;
a battery disposed within the electronics cavity, and configured to provide a first power supply signal to the control electronics and the high voltage power supply, the first power supply signal is a lower voltage than the second power supply signal; and
a thermal insulating material disposed on at least one wall of the electronics utilities cavity.

20. The carrier body of claim 19, wherein thermal breaks comprise a first material and the first and second body members comprise a second material, the first material comprises a lower thermal conductivity than the second material.
